(19) United States
(12) Patent Application Publication
(10) Pub. No.: US 2017/0025308 A1
(43) Pub. Date: Jan. 26, 2017

(54) METHOD OF CLEANING BOTTOM OF VIA HOLE AND METHOD OF MANUFACTURING SEMICONDUCTOR DEVICE

(71) Applicant: Tokyo Electron Limited, Tokyo (JP)

(72) Inventor: Kenji MATSUMOTO, Miyagi (JP)

(21) Appl. No.: 15/065,667

(22) Filed: Mar. 9, 2016

(30) Foreign Application Priority Data
Mar. 10, 2015 (JP) 2015-047015

(51) Int. Cl. H01L 21/768; H01L 21/306

(52) U.S. Cl. CPC H01L 21/76879; H01L 21/30604; H01L 21/76883

(57) ABSTRACT

In a method of cleaning a bottom of a via hole, a copper oxide on a surface of an underlying Cu wiring exposed at the bottom of the via hole is removed before forming a Cu wiring in a trench and the via hole extended between the trench and the underlying Cu wiring. The trench and the via hole are formed in a predetermined pattern in an interlayer insulating film of a substrate. Reducing species containing a metal in a state capable of reducing the copper oxide is supplied to the bottom of the via hole. The metal has a higher oxidation tendency than Cu and an oxide of the metal has a lower electrical resistance than the copper oxide. The copper oxide is removed by reducing the copper oxide and the oxide of the metal is generated through a reaction between the metal in the reducing species and the copper oxide.

### CROSS-REFERENCE TO RELATED APPLICATIONS

This application claims priority to Japanese Patent Application No. 2015-047015 filed on Mar. 10, 2015, the entire contents of which are incorporated herein by reference.

### FIELD OF THE INVENTION

The disclosure relates to a method of reducing and removing a copper oxide formed on a surface of a Cu wiring at the bottom of a via hole and a method of manufacturing a semiconductor device.

### BACKGROUND OF THE INVENTION

As an integration density of a semiconductor device is increased, a geometric dimension of an internal wiring or a semiconductor element is miniaturized. Due to demands for a high speed, miniaturization and high integration of the semiconductor device, there is employed a multilayer interconnection structure in which Cu wirings having a low resistance and a low electromigration are buried in multilayers in an interlayer insulating film. Such a multilayer interconnection structure is formed by a dual damascene method. In other words, a trench as a wiring groove is formed in the interlayer insulating film and a via hole to be connected to an underlying Cu wiring is formed at a bottom portion of the trench. Then, the trench and the via hole are filled with Cu. Before they are filled with Cu, a barrier film for preventing diffusion of Cu is formed on inner walls of the trench and the via hole.

A surface of Cu is easily oxidized in the atmosphere. Therefore, before the trench and the via hole are filled with Cu, copper oxide is formed on a surface of the underlying Cu wiring which is exposed at the bottom of the via hole. The copper oxide is an insulating material and increases resistance. Therefore, before the formation of the barrier film, there is performed a cleaning process for reducing and removing the copper oxide at the bottom of the via hole.

As a technique for removing an oxide such as copper oxide, there is known a reduction process using H₂ such as H₂ annealing, H₂ radical processing, H₂ plasma processing or the like. In addition, dry cleaning using an organic acid such as formic acid is suggested (e.g., Japanese Patent Application Publication No. 2009-043976). Further, a method for removing an oxide by argon sputtering etching is suggested (e.g., Japanese Patent Application Publication No. 2010-192467).

However, the reduction process using H₂ such as the H₂ annealing, the H₂ radical processing, the H₂ plasma processing or the like may adversely affect the device due to its high processing temperature. In the H₂ annealing, it is not possible to sufficiently reduce the copper oxide. In the H₂ radical processing and the H₂ plasma processing, an effect of reduction in a narrow pattern is insufficient. Further, in the H₂ plasma processing, the underlying insulating film may be damaged.

The organic acid dry cleaning is disadvantageous in that copper scatters due to the insufficient reduction of copper oxide.

The removal method using argon sputtering etching is disadvantageous in that the effect of removal in the narrow pattern is insufficient and also in that the damage to the underlying insulating film or the scattering of Cu may occur.

### SUMMARY OF THE INVENTION

In view of the above, the disclosure provides a method of cleaning the bottom of a via hole, which is capable of preventing an adverse effect on an underlying insulating film and scattering of Cu and realizing low resistance by effectively removing copper oxide formed on a surface of a Cu wiring at the bottom of the via hole even in a narrow pattern, and a method of manufacturing a semiconductor device.

In accordance with a first aspect, there is provided a method of cleaning a bottom of a via hole which removes a copper oxide on a surface of an underlying Cu wiring exposed at the bottom of the via hole before formation of a Cu wiring in a trench and the via hole extended between the trench and the underlying Cu wiring. The trench and the via hole are formed in a predetermined pattern in an interlayer insulating film of a substrate. In the method, reducing species containing a metal in a state capable of reducing the copper oxide is supplied to the bottom of the via hole. The metal has a higher oxidation tendency than Cu and whose oxide has a lower electrical resistance than the copper oxide. The copper oxide is removed by reducing the copper oxide and the oxide of the metal is generated through a reaction between the metal contained in the reducing species and the copper oxide on the surface of the underlying Cu wiring.

In the first aspect, the metal may be Mn, Zn, Sn or In. The metal is deposited as the reducing species by PVD on a surface of the substrate which includes the bottom of the via hole, and the deposited metal and the copper oxide on the surface of the underlying Cu wiring can also react with each other by heating. In this case, it is preferable to remove moisture by performing a degas process on the substrate before the cleaning of the bottom of the via hole.

In accordance with a second aspect, there is provided a method of cleaning a bottom of a via hole which removes a copper oxide on a surface of an underlying Cu wiring exposed at the bottom of the via hole before formation of a Cu wiring in a trench and the via hole extended between the trench and the underlying Cu wiring. The trench and the via hole are formed in a predetermined pattern in an interlayer insulating film of a substrate. In the method, Mn-containing material which contains Mn in a state capable of reducing the copper oxide is supplied to the bottom of the via hole as reducing species. The copper oxide is removed by reducing the copper oxide and a manganese oxide is generated through a reaction between the Mn-containing material and the copper oxide on the surface of the underlying Cu wiring.

In the second aspect, Mn is deposited as the Mn-containing material by PVD on a surface of the substrate which includes the bottom of the via hole, and the deposited Mn and the copper oxide on the surface of the underlying Cu wiring can react with each other by heating. A manganese film is formed by CVD on a surface of the substrate which includes the bottom of the via hole by using an organic Mn compound gas as the Mn-containing material, and the manganese film and the copper oxide on the surface of the underlying Cu wiring can also react with each other. In this case, it is preferable to remove moisture by performing a degas process on the substrate before the cleaning of the bottom of the via hole.

In accordance with a third aspect, there is provided a method of a method of manufacturing a semiconductor device, which forms a Cu wiring connected to an underlying Cu wiring by filling a Cu-based film in a trench and the via hole extended between the trench and the underlying Cu wiring. The trench and the via hole are formed in a predetermined pattern in an interlayer insulating film of a substrate. In the method, a bottom of the via hole is cleaned by supplying reducing species containing a metal which has a higher oxidation tendency than Cu and whose oxide has a lower electrical resistance than a copper oxide formed on the surface of the underlying Cu wiring, in a state capable of reducing the copper oxide. The copper oxide is removed by reducing the copper oxide and the oxide of the metal is generated through a reaction between the metal contained in the reducing species and the copper oxide. Next, a barrier film is formed on a surface of the interlayer insulating film. A Cu-based film is filled in the trench and the via hole. A Cu wiring is formed by polishing a surface of the substrate including the Cu-based film.

In accordance with a forth aspect, there is provided a method of manufacturing a semiconductor device, which forms a Cu wiring connected to an underlying Cu wiring by filling a Cu-based film in a trench and a via hole extended between the trench and the underlying Cu wiring. The trench and the via hole are formed in a predetermined pattern in an interlayer insulating film of a substrate. In the method, the bottom of the via hole is cleaned by supplying to the bottom of the via hole a Mn-containing material which contains Mn in a state capable of reducing a copper oxide formed on the surface of the underlying Cu wiring as reducing species, and the copper oxide is removed by reducing the copper oxide and generating a manganese oxide through a reaction between the Mn-containing material and the copper oxide. Next, a barrier film is formed on the surface of the interlayer insulating film. The Cu-based film is filled in the trench and the via hole. A Cu wiring is formed by polishing a surface of the substrate including the Cu-based film.

In the third aspect and the forth aspect, the filling the Cu-based film in the trench and the via hole may be performed by Cu plating.

The filling the Cu-based film in the trench and the via hole may be performed by PVD. In this case, before the filling the Cu-based film in the trench and the via hole, a layer to be wetted may be further formed on the surface of the barrier film. The layer to be wetted is made of a metal which can be wetted by Cu or Cu alloy. It is preferable to form the Cu-based film in the trench and the via hole by PVD under a condition in which the Cu-based film is movable on the layer. The layer is preferably made of Ru or Co. The layer is preferably formed by CVD.

### BRIEF DESCRIPTION OF THE DRAWINGS

The objects and features of the disclosure will become apparent from the following description of embodiments, given in conjunction with the accompanying drawings, in which:

FIGS. 1A to 1C schematically show concept of a method of cleaning the bottom of a via hole according to an embodiment;

FIG. 2 is a standard free energy-temperature diagram (Ellingham diagram) for an oxide formation, which shows oxidation tendency of metals;

FIG. 3 is a cross sectional view of an inductively coupled plasma (ICP) sputtering apparatus as an example of a PVD apparatus for performing cleaning by supplying a metal Mn as reducing species to via hole bottom;

FIGS. 4A and 4B show states of a via hole bottom of a wafer W in the case of cleaning the via hole bottom by the apparatus shown in FIG. 3;

FIG. 5 is a cross sectional view of an example of a CVD apparatus for performing cleaning by supplying an organic Mn compound as reducing species to the via hole bottom;

FIGS. 6A to 6C show states of a via hole bottom of a wafer in the case of cleaning the via hole bottom by the apparatus shown in FIG. 5;

FIG. 7 is a TEM image showing a cross section of a sample obtained by performing a CVD process using an organic Mn compound gas on a blanket Cu film having on a surface thereof copper oxide and then forming a Cu film on the blanket Cu film;

FIG. 8 shows a result of analysis obtained by backside SIMS of the sample shown in FIG. 7;

FIG. 9 is a TEM image showing a cross section of a sample obtained by forming a dual damascene pattern by forming a trench and a via hole in an interlayer insulating film, forming copper oxide on the surface of the underlying Cu wiring at the via hole bottom by air exposure, performing a CVD process using an organic Mn compound gas, and filling Cu in the via hole and the trench;

FIG. 10 is a flowchart showing a first example of a method of manufacturing semiconductor device;

FIGS. 11A to 11G are cross sectional views for explaining the first example of the method of manufacturing semiconductor device;

FIG. 12 is a flowchart showing a second example of the method of manufacturing semiconductor device;

FIGS. 13A to 13H are cross sectional views for explaining the second example of the method of manufacturing semiconductor device;

FIG. 14 is a schematic diagram of a film forming system used for the first example of the method of manufacturing semiconductor device; and

FIG. 15 is a schematic diagram of a film forming system used for the second example of the method of manufacturing semiconductor device.

### DETAILED DESCRIPTION OF THE EMBODIMENTS

Hereinafter, embodiments will be described in detail with reference to the accompanying drawings.

<Method of Cleaning Via Hole Bottom>

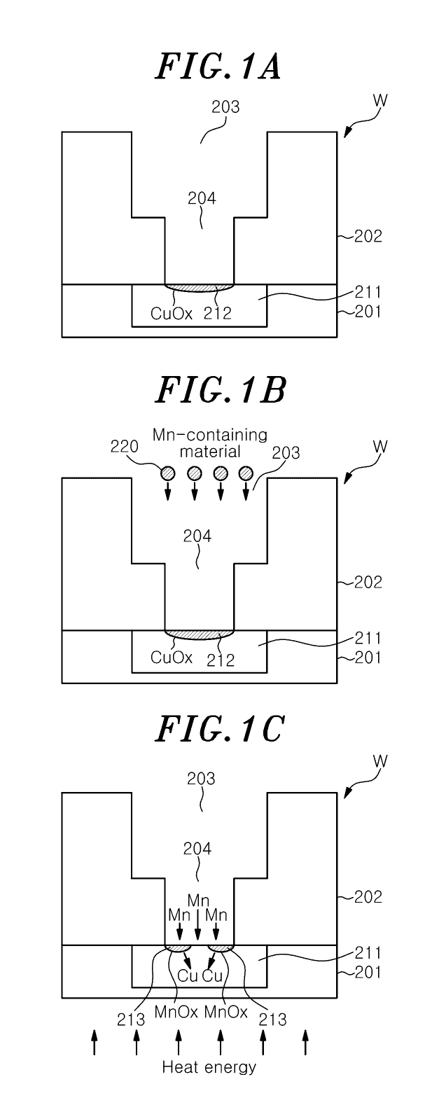

First, a method of cleaning the bottom of a via hole according to an embodiment will be described. FIGS. 1A to 1C schematically show concept of the method of cleaning the bottom of the via hole according to the embodiment.

Here, a via hole bottom cleaning process is performed on a semiconductor wafer (hereinafter, simply referred to as “wafer”) W in which an interlayer insulating film 202 that is an Si-containing film, such as an SiO₂ film, a low dielectric constant (low-k) film (SiCO, SiCOH or the like) or the like, is formed on a lower structure 201 (details thereof are omitted) including a underlying Cu wiring 211, and a trench 203 and a via hole 204 connected to the underlying Cu wiring 211 from a bottom portion of the trench 203 are formed in a predetermined pattern in the interlayer insulating film 202, as shown in FIG. 1A. Specifically, a copper oxide 212 is formed on a surface of the underlying Cu wiring 211 exposed at a via hole bottom, i.e., a bottom of the via hole. The copper oxide is removed by reduction. The copper oxide is Cu₂O or CuO. Hereinafter, both of Cu₂O and CuO are referred to as CuOx.

In the cleaning of the via hole bottom, reducing species containing a metal, which has a higher oxidation tendency than Cu and whose oxide has a lower electrical resistance than copper oxide (CuOx), in a state capable of reducing copper oxide is supplied to the via hole bottom. Such a metal may be, e.g., Mn. As shown in FIG. 1B, a Mn-containing material 220 capable of reducing copper oxide is supplied as reducing species to the wafer W having the above-described structure. As shown in FIG. 1C, by applying predetermined heat energy, Mn in the Mn-containing material becomes a manganese oxide 213 by attracting oxygen around, and the copper oxide 212 at the via hole bottom is reduced by Mn in the reducing species to be a metal Cu.

The manganese oxide may be MnO, Mn₃O₄, Mn₂O₃, MnO₂ and the like. Therefore, those oxides are expressed by “MnOx” in FIGS. 1A to 1C and the following description.

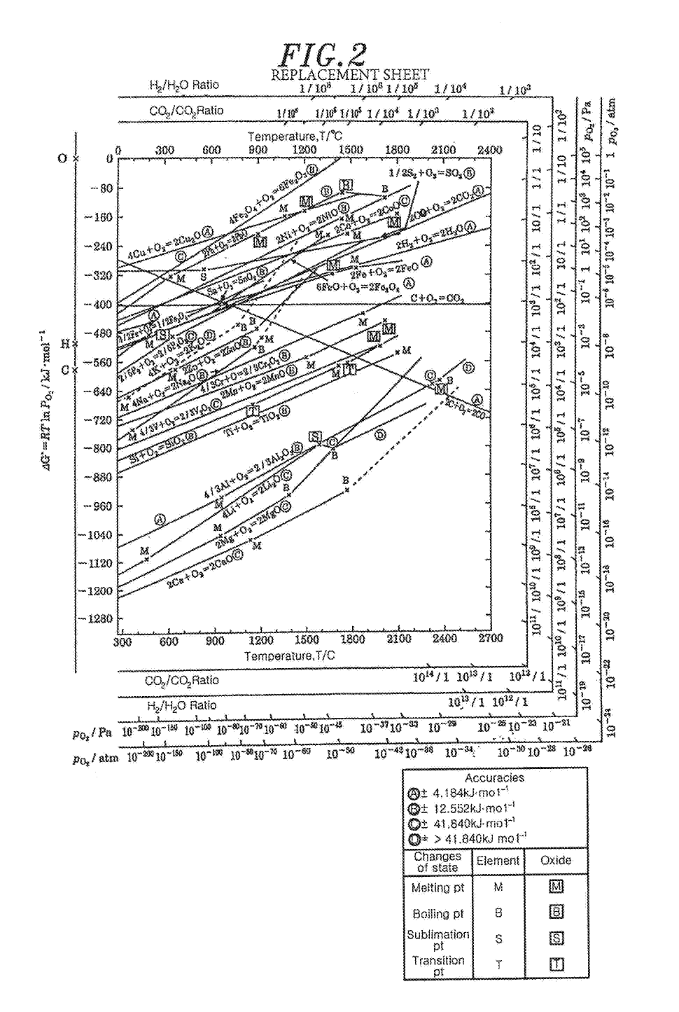

The oxidation tendency of metals can be found in the standard free energy-temperature diagram (Ellingham diagram) of oxide formation (Iron and Steel Handbook 1st Edition, Iron and Steel Institute of Japan) illustrated in FIG. 2. In the oxide formation line below the line of 4Cu+O₂=2Cu₂O shown in FIG. 2, the oxide formation free energy is lower than Cu (negative side is large), so that the oxidation tendency is increased. The intensity of the oxidation tendency can be determined by comparing the oxide formation free energy.

As can be seen from the Ellingham diagram, in the case of using the Mn-containing material as the reducing species, the oxidation tendency of Mn is stronger than that of Cu. For example, at 300K, the standard free energy of Cu₂O per one mole of oxygen is −295 kJ, whereas the standard free energy of MnO is −725 kJ which is larger in a negative side. Further, in the copper oxide (CuOx), the number of oxygen atoms that can be bonded to a single Cu atom is 0.5 to 1. On the other hand, in the manganese oxide (MnOx), the number of oxygen atoms that can be bonded to a single Mn atom is 1 or 2 so that Mn attracts a larger number of oxygen atoms compared to Cu. Therefore, by supplying a Mn-containing material to the via hole bottom, the copper oxide is reduced by Mn and a manganese oxide is generated, as shown in FIGS. 1A to 1C. As some kinds of the manganese oxide, e.g., MnO₂, have a lower electrical resistance than copper oxide that is an insulator, it is expected that resistance is decreased overall when the manganese oxide is generated by reducing the copper oxide compared to when the copper oxide is formed at the via hole bottom.

Zn, Sn, In or the like besides Mn may be used as a metal which has a higher oxidation tendency than copper oxide and whose oxide has a lower electrical resistance than copper oxide. ZnO, SnO₂ and In₂O₃ are generated as oxides of Zn, Sn and In, respectively.

As a specific method for performing cleaning by supplying such reducing species to the via hole bottom, there may be employed PVD (Physical Vapor Deposition) and CVD (Chemical Vapor Deposition).

(PVD)

PVD includes, e.g., a sputtering method. For example, ionized PVD (iPVD) in which a film is formed by attracting ions to the wafer may be preferably used. The via hole bottom can be cleaned by supplying, e.g., a metal Mn, as reducing species by PVD.

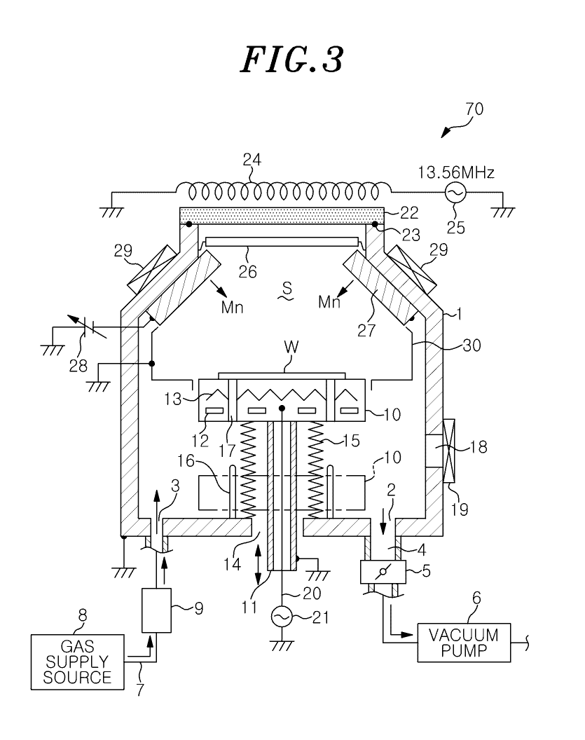

FIG. 3 is a cross sectional view of an ICP (Inductively Coupled Plasma) sputtering apparatus as an example of a PVD apparatus for performing cleaning by supplying the metal Mn as the reducing species to the via hole bottom.

As shown in FIG. 3, a plasma sputtering apparatus 70 includes a processing chamber 1 that is grounded and made of a metal such as aluminum or the like. A gas exhaust port 2 and a gas inlet port 3 are provided at a bottom portion of the processing chamber 1. A gas exhaust line 4 is connected to the gas exhaust port 2. A throttle valve 5 and a vacuum pump 6 for pressure control are connected to the gas exhaust line 4. A gas supply line 7 is connected to the gas inlet port 3. A gas supply source 8 for supplying a plasma excitation gas, e.g., Ar gas or the like, is connected to the gas supply line 7. A gas control unit 9 including a gas flow rate controller, a valve and the like is installed in the gas supply line 7.

Provided in the processing chamber 1 is a mounting table 10 for mounting thereon a wafer W as a substrate to be processed. The mounting table 10 is supported by a cylindrical support 11. The mounting table 10 is made of a metal, e.g., an aluminum alloy or the like. The mounting table 10 is grounded via the support 11. The mounting table 10 has therein a cooling jacket 12 through which a coolant of a predetermined temperature circulates and a resistance heater 13 coated with an insulator. The mounting table 10 is controlled to a predetermined temperature by the cooling jacket 12 and the resistance heater 13.

A lower portion of the support 11 extends downward through an insertion hole 14 formed at a bottom central portion of the processing chamber 1. The support 11 is vertically moved by an elevation unit (not shown) and the mounting table 10 is vertically moved by the vertical movement of the support 11.

An extensible/contractible metal bellows 15 surrounds the support 11. The metal bellows 15 has an upper end coupled to a bottom surface of the mounting table 10 and a lower end coupled to a top surface of the bottom portion of the processing chamber 1. The mounting table 10 can be vertically moved while maintaining the airtightness in the processing chamber 1.

A plurality of, e.g., three (only two are shown in FIG. 3) supporting pins 16 are vertically provided on the top surface of the bottom portion of the processing chamber 1. A plurality of insertion holes 17 through which the supporting pins 16 are inserted are formed in the mounting table 10. Therefore, when the mounting table 10 is lowered, the wafer W can be received by upper end portions of the supporting pins 16 that have penetrated through the insertion holes 17, and then can be transferred to and from a transfer arm (not shown) that has entered from the outside. Provided at a lower sidewall of the processing chamber 1 is a loading/unloading port 18 through which the transfer arm enters. The loading/unloading port 18 can be opened and closed by a gate valve 19.

A high frequency power supply 21 for bias is connected to the mounting table 10 through a power feed line 20. A high frequency bias power is applied to the wafer W on the mounting table 10 by the high frequency power supply 21. The high frequency bias power preferably has a frequency ranging from 400 kHz to 60 MHz, e.g., 13.56 MHz.

A transmitting plate 22 made of a dielectric material is airtightly provided at a ceiling portion of the processing chamber 1 through a seal member 23. An induction coil 24 for generating a plasma in the processing space S in the processing chamber 1 is provided above the transmitting plate 22. A high frequency power supply 25 for plasma generation is connected to the induction coil 24. By supplying a high frequency power having a frequency of, e.g., 13.56 MHz, from the high frequency power supply 25 to the induction coil 24, an induction field is generated in the processing space S through the transmitting plate 22. A plasma of Ar gas supplied into the processing chamber 1 is generated by the induction field thus generated.

A baffle plate 26 is provided immediately below the transmitting plate 22. An annular Mn target 27 having an inwardly inclined cross section (truncated cone shape) is provided below the baffle plate 26 to surround the upper portion of the processing space S. A DC power supply 28 for supplying a DC power for attracting Ar ions is connected to the target 27. An AC power supply may be used instead of the DC power supply.

A magnet 29 is provided at an outer side of the target 27. The target 27 is sputtered by Ar ions in the plasma, so that Mn is released therefrom. Most of the metal Mn is ionized while passing through the plasma.

A cylindrical protection cover member 30 made of a metal, e.g., aluminum, copper, or the like, is provided below the target 27 to surround the processing space S. The protection cover member 30 is grounded.

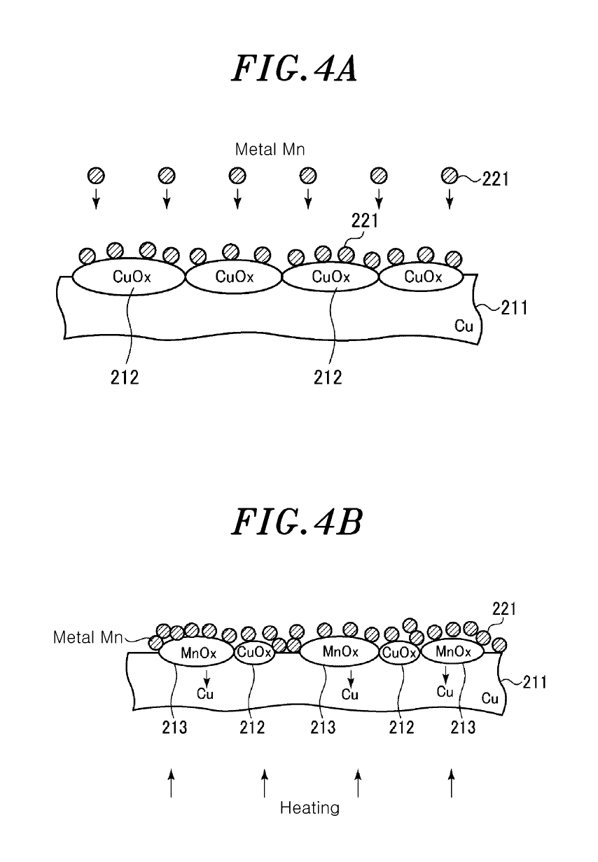

Next, the cleaning operation using the metal Mn as the reducing species in the plasma sputtering apparatus 70 configured as described above will be described with reference to FIGS. 4A and 4B. FIGS. 4A and 4B show states of the underlying Cu wiring existing at the via hole bottom in the case of cleaning the via hole bottom.

The wafer W having the structure shown in FIGS. 1A to 1C is loaded into the processing chamber 1 shown in FIG. 3 and then mounted on the mounting table 10. The mounting table 10 is controlled to a predetermined temperature by controlling the power supply to the resistance heater 13 and the coolant supply to the cooling jacket 12.

In that state, Ar gas is supplied at a predetermined flow rate, and the processing chamber 1 is evacuated by the vacuum pump 6 and maintained at a predetermined vacuum level while controlling the throttle valve 5. Thereafter, the DC power is applied from the DC power supply 28 to the target 27, and the high frequency power (plasma power) is applied from the high frequency power supply 25 to the induction coil 24. A predetermined high frequency bias power is applied from the high frequency power supply 21 to the mounting table 10.

As a consequence, in the processing chamber 1, an Ar plasma is generated by the high frequency power applied to the induction coil 24, thereby generating Ar ions. The Ar ions are attracted to the Mn target 27 by the DC voltage applied to the Mn target 27. Thus, the Mn target 27 is sputtered and the metal Mn particles are released from the Mn target 27.

The particles from the Mn target 27 are mostly ionized while passing through the plasma. The ionized particles are scattered downward. The ionization rate at this time is controlled by the high frequency power supplied from the high frequency power supply 25.

When the ions are introduced into an ion sheath region, which is formed above the wafer W with a thickness of about a few mm, by the high frequency bias power applied from the high frequency power supply 21 to the mounting table 10, the ions are attracted with strong directivity to be accelerated toward the wafer W. Accordingly, as shown in FIG. 4A, the metal Mn 221 as the Mn-containing material is supplied to the surface of the wafer W and deposited on the surface of the wafer W including the underlying Cu wiring 211 existing at the via hole bottom. At this time, as it is preferable to supply the amount of the metal Mn 221 which is enough to reduce the copper oxide (CuOx), an average film thickness of a few nm may be obtained by flash film formation. The step coverage of the PVD is not so good. Thus, in such the flash film formation, the metal Mn is deposited on the field portion or the bottom portion of the trench 203 or the via hole 204 and is hardly deposited on the sidewall of the trench 203 or the via hole 204. Further, a discontinuous state such as an island shape or the like may occur even at the portion where the metal Mn is deposited. Since, however, the metal Mn serving as the reducing species is supplied in order to attract ambient oxygen, the film may not be necessarily continuous and may be discontinuous. In this case, it is preferable that at least 50% of the surface of the wafer W is covered by the metal Mn.

In the plasma sputtering process, the wafer W is heated and sputtered by controlling the temperature of the mounting table 10 to 100° C. to 300° C., or the wafer W is sputtered at a room temperature and then annealed at 100° C. to 300° C. As a consequence, as shown in FIG. 4B, the deposited metal Mn 221 reacts with the copper oxide (CuOx) 212 on the surface of the underlying Cu wiring 211 exposed at the bottom portion of the via hole 204; the copper oxide (CuOx) 212 is reduced to metal Cu and becomes a part of the underlying Cu wiring 211; and the metal Mn 221 is oxidized to the manganese oxide (MnOx) 213.

The PVD is not limited to iPVD, and a conventional sputtering, ion plating or the like may be used. Further, it is preferable to substantially completely remove moisture adhered to the wafer W by performing a degas process on the wafer W at about 250° C. before the PVD process.

(CVD)

In the case of using CVD as a method for supplying reducing species, a metal Mn film is deposited by using an organic Mn compound gas as reducing species. As the organic Mn compound, it is preferable to use a cyclopentadienyl-based manganese compound. The cyclopentadienyl-based manganese compound may be bis(alkylcyclopentadienyl)manganese expressed by a general formula Mn(RC₅H₄)₂ such as Cp₂Mn[═Mn(CH₅)₂], (MeCp)₂Mn[═Mn(CH₃CH₄)₂], (EtCp)₂Mn[═Mn(C₂H₅C₅H₄)₂], (i-PrCp)₂Mn[═Mn(C₃H₇C₅H₄)₂], and (t-BuCp)₂Mn[═Mn(C₄H₉C₅H₄)₂].

As another manganese compound, it is also possible to use a carbonyl-based manganese compound, a betadiketone-based manganese compound, an amidinate-based manganese compound, and an amideaminoalkane-based manganese compound.

The carbonyl-based manganese compound may be dimanganese decacarbonyl (Mn₂(CO)₁₀) or methylcyclopentadienyl manganese tricarbonyl ((CH₃C₅H₄)Mn(CO)₃).

The amidinate-based manganese compound may be bis (N,N′-dialkylacetamidinate) manganese expressed by a general formula Mn(R¹N—CR³—NR²)₂ which is disclosed in U.S. Patent Application Publication No. US2009/0263965 A1.

The amideaminoalkane-based manganese compound may be bis(N,N′-1-alkylamide-2-dialkylaminoalkane) manganese expressed by a general formula Mn(R¹N—Z—NR²₂)₂ which is disclosed in PCT Publication No. 2012/060428. Here, the notations R, R¹, R² and R³ in the general formula denote functional groups expressed by —CₙH₂ₙ₊₁ (n being an integer greater than or equal to 0) and the notation Z denotes a functional group expressed by —CₙH₂ₙ— (n being an integer greater than or equal to 1).

The organic Mn compound is in a solid or a liquid state at a room temperature. For example, a gas obtained by heating the organic Mn compound to about 80° C. is used as reducing species. In the case of performing a CVD process by supplying the organic Mn compound as the reducing species, the degas process is performed on the wafer W at about 250° C. before the CVD process so that moisture or the like adhered to the wafer W can be substantially completely removed. This is because, if the degas process is not performed, the moisture adhered to the wafer W reacts with the organic Mn compound and the manganese oxide is deposited on the interlayer insulating film of the pattern as well as on the copper oxide at the via hole bottom.

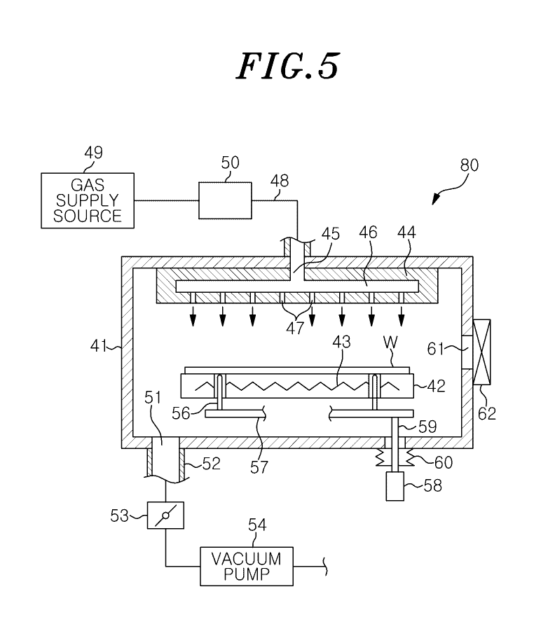

FIG. 5 is a cross sectional view showing an example of a CVD apparatus for performing cleaning by supplying an organic Mn compound as reducing species to the via hole bottom.

The CVD apparatus 80 includes a tubular processing chamber 41 made of, e.g., aluminum or the like. In the processing chamber 41, a mounting table 42 made of ceramic, e.g., AlN or the like, for mounting thereon the wafer W is provided. A heater 43 is provided in the mounting table 42. The wafer W is heated by the heater 43 through the mounting table 42.

A shower head 44 for introducing a processing gas for film formation, a purge gas, or the like into the processing chamber 41 in a shower shape is provided at a ceiling of the processing chamber 41 to face the mounting table 42. A gas inlet port 45 is formed at an upper portion of the shower head 44. A gas diffusion space 46 is formed in the shower head 44. A plurality of gas injection holes 47 is formed on a bottom surface of the shower head 44. A gas supply line 48 is connected to the gas inlet port 45. A gas supply source 49 for supplying an organic Mn compound gas for film formation, a purge gas, or the like is connected to the gas supply line 48. A gas control unit 50 including a gas flow rate controller, a valve, and the like is installed in the gas supply line 48.

In the gas supply source 49, the organic Mn compound maintained in a liquid state by heating is vaporized at about 80° C. by a bubbling container or a vaporizer, and then supplied to the gas supply line 48

A gas exhaust port 51 is provided at a bottom portion of the processing chamber 41. A gas exhaust line 52 is connected to the gas exhaust port 51. A throttle valve 53 and a vacuum pump 54 for pressure control are installed in the gas exhaust line 52, so that the processing chamber 41 can be evacuated.

Three wafer supporting pins 56 (only two being shown) for transferring the wafer can protrude beyond and retreat below the surface of the mounting table 42. The wafer supporting pins 56 are fixed on a supporting plate 57. The wafer supporting pins 56 are vertically moved together with the supporting plate 57 by vertically moving a rod 59 by a driving unit 58 such as an air cylinder or the like. Reference numeral 60 denotes a bellows. A wafer loading/unloading port 61 is formed at a sidewall of the processing chamber 41. The wafer loading/unloading port 61 can be opened/closed by a gate valve 62. The loading/unloading of a wafer W can be performed in a state where the gate valve 62 is opened.

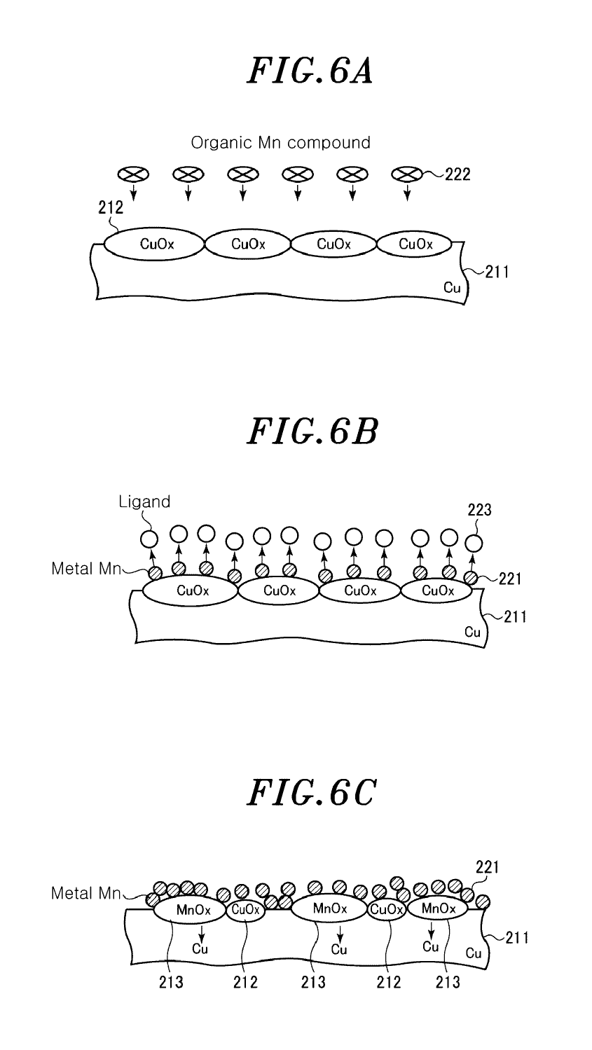

Hereinafter, a cleaning operation using an organic Mn compound as reducing species in the CVD apparatus 80 configured as described above will be described with reference to FIGS. 6A to 6C. FIGS. 6A to 6C show states of the underlying Cu wiring existing at the via hole bottom in the case of cleaning the via hole bottom.

After the moisture is removed by performing the degas process on the wafer W having the structure shown in FIGS. 1A to 1C at about 250° C., the gate valve 62 is opened and the wafer W that has been subjected to the degas process is mounted on the mounting table 42. Then, the gate valve 62 is closed and the processing chamber 41 is exhausted by the vacuum pump 54. The pressure in the processing chamber 41 is controlled to a predetermined level, and the wafer W on the mounting table 42 is heated to a predetermined temperature by the heater 43. In that state, the organic Mn compound gas is introduced as reducing species from the gas supply source 49 into the processing chamber 41 through the gas supply line 48 and the shower head 44. An organic Mn compound gas 222 is supplied to the wafer W as shown in FIG. 6A. At this time, the heating temperature of the wafer W can be appropriately set depending on purposes. When Mn is selectively supplied to the copper oxide exposed at the via hole bottom without being supplied onto the interlayer insulating film, it is preferable to set the heating temperature of the wafer W to be lower than a thermal decomposition temperature of the organic Mn compound (e.g., 250° C. in the case of bis(N,N′-1-alkylamide-2-dialkylaminoalkane)manganese). When it is required to ensure strong reducing power due to a thick film of the copper oxide exposed at the via hole bottom, it is preferable to set the heating temperature of the wafer W to be higher than the thermal decomposition temperature of the organic Mn compound.

When the organic Mn compound gas 222 is adsorbed onto the surface of the wafer W, a ligand 223 or the like of the organic Mn compound is separated and the metal Mn 221 is supplied to the surface of the wafer W and deposited on the surface of the wafer W including the surface of the underlying Cu wiring 211 at the via hole bottom, as shown in FIG. 6B. As shown in FIG. 6C, the metal Mn 221 supplied to the via hole bottom obtains oxygen from the copper oxide (CuOx) on the surface of the underlying Cu wiring 211, thereby generating the manganese oxide (MnOx) 213. The copper oxide (CuOx) 212 is reduced to a metal Cu and becomes a part of the underlying Cu wiring 211. The deposited film thickness of the manganese oxide (MnOx) 213 at this time may be about a few nm. However, it is preferable to change the deposited film thickness of the manganese oxide depending on the degree of oxidation of the underlying Cu wiring surface.

The degas process may be performed by the CVD apparatus. The degas process may be performed at a temperature higher than or equal to that in the CVD process. For example, when the degas process is performed at a pressure of 1330 Pa and the CVD process is performed at a pressure of 13 Pa, the heat transfer to the wafer W is changed even if the temperature of the mounting table is maintained at a constant level. Therefore, the temperature of the degas process can be set to be higher than the temperature of the CVD process. In that case, a degas apparatus may not be provided separately.

### Effect of the Embodiment

As described above, in the present embodiment, the copper oxide on the surface of the underlying Cu wiring is reduced by supplying to the via hole bottom the reducing species containing Mn having a higher oxidation tendency than Cu, and the manganese oxide having a lower electrical resistance than the copper oxide is generated. Therefore, the copper oxide can be reliably reduced even in a narrow pattern. As a result, it is possible to obtain the low resistance and prevent the damage to the underlying insulating film or the scattering of Cu.

<Test Result>

Hereinafter, the result of the test in which the copper oxide is reduced by using the organic Mn compound as the reducing species will be described.

First, a Cu film (blanket film) was formed on a CVD-SiO₂ film on a Si wafer by PVD (plasma sputtering). Then, copper oxide was formed on the surface thereof by residual oxygen in the film forming apparatus and a degas process was performed. Next, (EtCp)₂Mn as an organic Mn compound was vaporized and introduced into the processing chamber and the CVD process was performed at a wafer temperature of 200° C. for 600 sec. Thereafter, a Cu film was formed thereon by the PVD (plasma sputtering), for convenience.

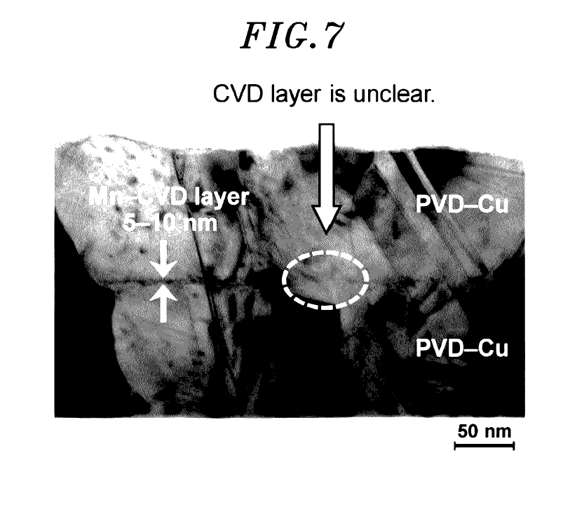

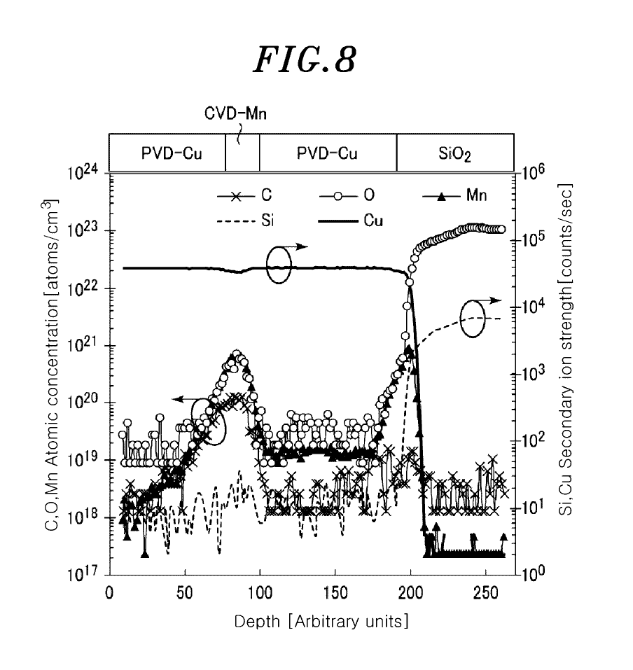

FIG. 7 shows a TEM (Transmission Electron Microscope) image of a cross section of a sample which is obtained by the above test. FIG. 8 shows a result of backside SIMS (Secondary Ion Mass Spectrometry) analysis. As shown in FIG. 7, a discontinuous film having a thickness of 5 nm to 10 nm is formed between an upper and a lower Cu film. As shown in FIG. 8, the amount of Mn and O was increased at a portion where the CVD process using (EtCp)₂Mn was performed and the concentration of Mn and that of O was substantially the same. Therefore, it is clear that the copper oxide on the surface of the underlying Cu film is removed and the manganese oxide is formed. Since the copper oxide that is an insulator is replaced by the manganese oxide having a lower electrical resistance than the copper oxide, the low resistance of the wiring can be realized. Further, as shown in FIG. 7, the manganese oxide is generated discontinuously and the upper Cu film and the lower Cu film are connected at the portion where the manganese oxide does not exist, which is advantageous in realizing the low resistance of the wiring.

Next, a trench and a via hole are formed as a dual damascene pattern in the interlayer insulating film made of a CVD-SiO₂ film formed on the underlying Cu wiring of the Si wafer. By exposing the dual damascene pattern to the atmosphere, copper oxide was generated on the surface of the underlying Cu wiring at the via hole bottom. Then, the degas process was performed and (EtCp)₂Mn as an organic Mn compound was vaporized and introduced into the processing chamber. Next, the CVD process was performed at a wafer temperature of 200° C. for 600 sec. Thereafter, the via hole and the trench were filled with Cu by the PVD (plasma sputtering) and, then, the annealing process was performed at 400° C.

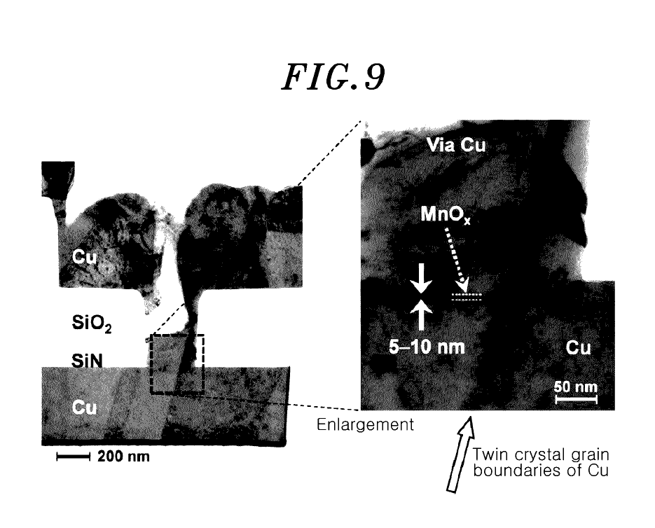

FIG. 9 shows a TEM image of the cross section at that time. As shown in FIG. 9, the manganese oxide film is discontinuously formed between the underlying Cu wiring and the embedded Cu. A twin crystal grain boundary is formed between the underlying Cu wiring and the embedded Cu. The underlying Cu wiring and the embedded Cu are continuously formed. In addition, as a result of the analysis of crystal grain plane orientation using EBSD (Electron Back Scatter Diffraction), it is clear that Cu in the via hole and the underlying Cu wiring have the same plane orientation and become integrated. From the above, it can be thought that copper oxide which is an insulator can be replaced by manganese oxide having a lower electrical resistance by performing a process using reducing species containing Mn. Further, it can be thought that the low resistance is obtained by the integration of the underlying Cu wiring with the embedded Cu which is supposed to be separated by copper oxide continuously formed on the surface of the underlying Cu wiring at the via hole bottom.

<Method of Manufacturing Semiconductor Device>

Hereinafter, a semiconductor device manufacturing method including the above-described via hole cleaning method will be described.

### First Example

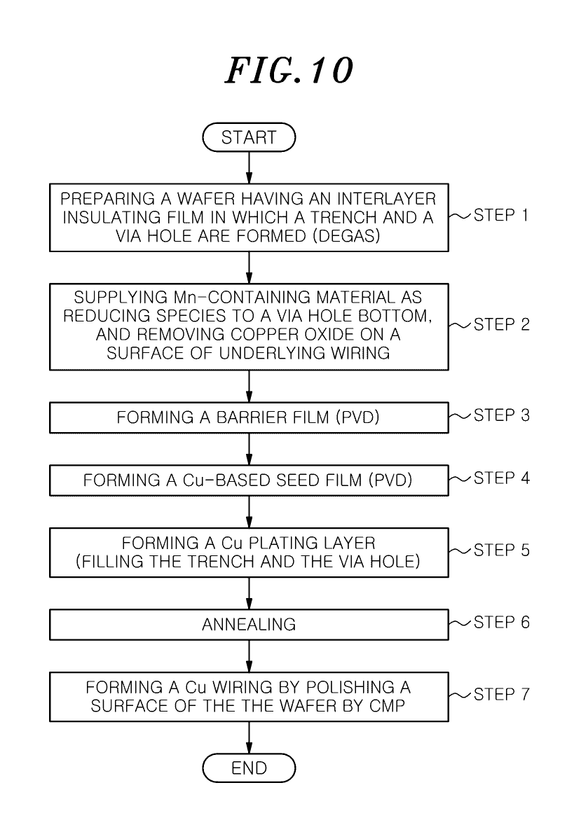

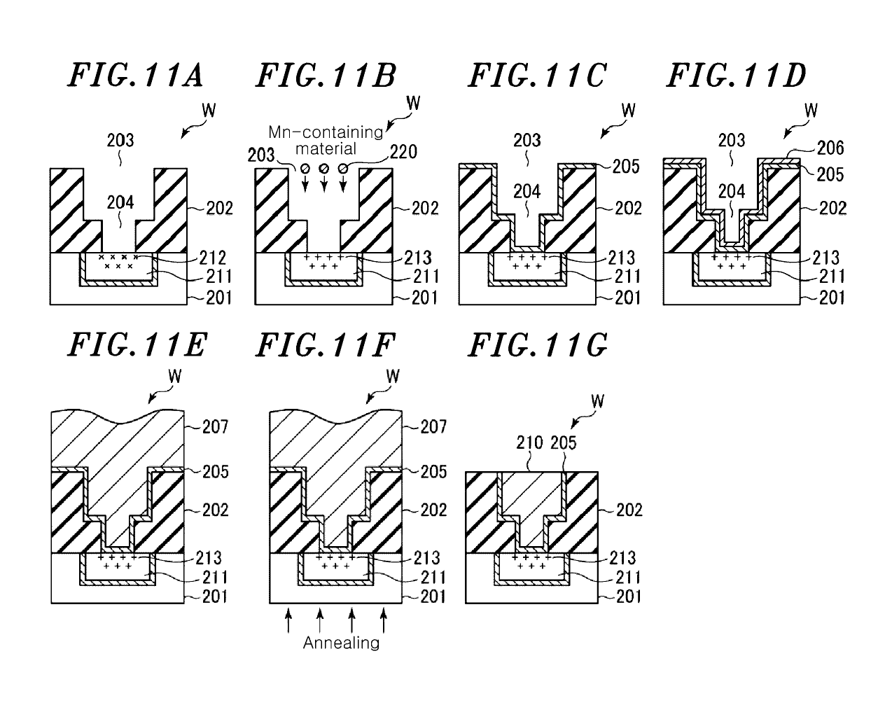

A first example of the semiconductor device manufacturing method will be described with reference to the flowchart of FIG. 10 and the cross sectional view of FIGS. 11A to 11G.

There is prepared a wafer W in which the interlayer insulating film 202 is formed on the lower structure 201 (details thereof are omitted) including the underlying Cu wiring 211. The interlayer insulating film 202 is formed of a SiO₂ film, a low-k film (SiCO, SiCOH or the like) or the like. The trench 203 and the via hole 204 are formed in a predetermined pattern in the interlayer insulating film 202. Moisture or the like adhered to the wafer W is removed by performing the degas process on the wafer W at, e.g., about 250° C., if necessary (step 1, FIG. 11A). At this time, the copper oxide (CuOx) 212 is formed on the surface of the underlying Cu wiring 211 exposed at the via hole bottom.

Next, the reducing species, e.g., the Mn-containing material 220, is supplied to the via hole bottom, and the copper oxide (CuOx) 212 on the surface of the underlying Cu wiring 211 is reduced and removed as described above (step 2, FIG. 11B). By heating the wafer W during the supply of the reducing species, the copper oxide (CuOx) is reduced and the metal (e.g., Mn) contained in the reducing species is oxidized to generate the manganese oxide (MnOx) 213 at least on the surface of the underlying Cu wiring 211. When the wafer W is at a room temperature, the above reaction may occur by performing an annealing process. Further, the above reaction may occur in a subsequent process including heating.

Next, the barrier film 205 which suppresses diffusion of Cu is formed on the surface of the wafer W including the surfaces of the trench 203 and the via hole 204 (step 3, FIG. 11C).

As the barrier film 205, it is preferable to use a film having a high barrier property to Cu and a low resistance, e.g., a Ti film, a TiN film, a Ta film, a TaN film, a dual film of Ta/TaN, a dual film of Ti/TiN, a dual film of Ti/TaN. Further, it is also possible to use a TaCN film, a W film, a WN film, a WCN film, a Zr film, a ZrN film, a V film, a VN film, a Nb film, a NbN film or the like. The resistance of the Cu wiring is decreased as the volume of Cu filled in the trench or the via hole is increased. Therefore, it is preferable to form a thin barrier film, and thus, the thickness thereof is preferably 1 nm to 10 nm and more preferably 1 nm to 5 nm. The barrier film can be formed by iPVD, e.g., plasma sputtering. Further, the barrier film may be formed by another PVD such as conventional sputtering, ion plating or the like, or by CVD, ALD, or CVD or ALD using a plasma.

Next, a Cu-based seed film 206 made of Cu or a Cu alloy is formed on the surface of the barrier film 205 by PVD (step 4, FIG. 11D). A thickness of the Cu-based seed film 206 is preferably 5 nm to 60 nm.

In the case of using a Cu alloy for the Cu-based seed film 206, Cu—Al and Cu—Mn may be representatively used. In addition, it is also possible to use Cu—Mg, Cu—Ag, Cu—Sn, Cu—Pb, Cu—Zn, Cu—Pt, Cu—Au, Cu—Ni, Cu—Co, Cu—Ti or the like.

The technique of the PVD used for forming the Cu-based seed film 206 is not limited. In order to form the Cu-based seed film 206 on an inner wall of a narrow trench or a narrow via hole, it is preferable to use iPVD for forming a film while attracting ions to the wafer. At this time, the PVD is preferably performed at a low temperature (e.g., −30° C. to 60° C.) so that Cu is not agglomerated.

Next, a Cu plating layer 207 is formed on the surface of the wafer W by Cu plating and, then, the trench 203 and the via hole 204 are filled with Cu (step 5, FIG. 11E). Thereafter, an annealing process is performed (step 6, FIG. 11F).

Then, the surface of the wafer W is planarized by removing the Cu plating layer 207, the Cu-based seed film 206, and the barrier film 205 by CMP (Chemical Mechanical Polishing) (step 7, FIG. 11G). Accordingly, a Cu wiring 210 connected to the underlying Cu wiring 211 is formed.

### Second Example

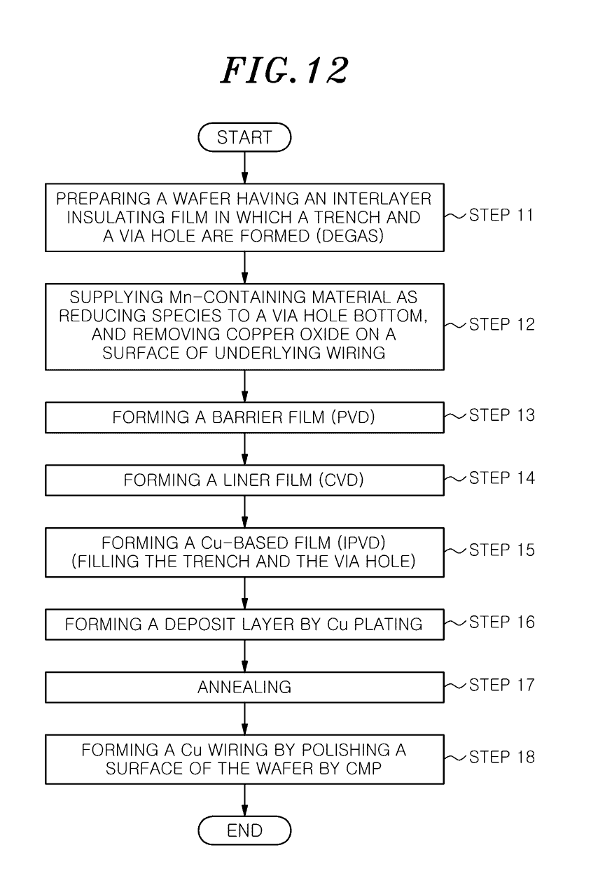

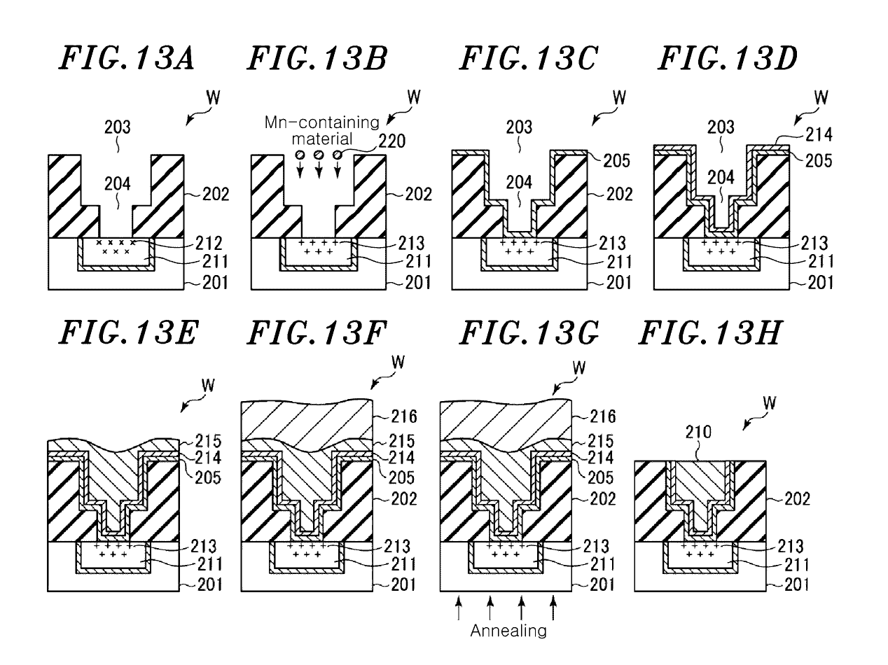

A second example of the semiconductor device manufacturing method will be described with reference to the flowchart of FIG. 12 and the cross sectional views of FIGS. 13A to 13H.

As in the step 1 of the first example, there is provided a wafer W in which the interlayer insulating film 202 is formed on the lower structure 201 (details thereof are omitted) including the underlying Cu wiring 211. The interlayer insulating film 202 is formed of a SiO₂ film, a low-k film (SiCO, SiCOH or the like) or the like. The trench 203 and the via hole 204 are formed in a predetermined pattern in the interlayer insulating film 202. Moisture or the like adhered to the wafer W is removed by performing a degas process on the wafer W at, e.g., about 250° C., if necessary (step 11, FIG. 13A). At this time, the copper oxide (CuOx) 212 is formed on the surface of the underlying Cu wiring 211 exposed at the via hole bottom.

Next, as in the step 2 of the first example, the Mn-containing material 220 is supplied as the reducing species and the copper oxide (CuOx) 212 on the surface of the underlying Cu wiring 211 exposed at the via hole bottom is reduced and removed as described above (step 12, FIG. 13B). At this time, the copper oxide (CuOx) is reduced by heating and the metal (e.g., Mn) contained in the reducing species is oxidized to generate the manganese oxide (MnOx) 213 at least on the surface of the underlying Cu wiring 211.

Next, as in the step 3 of the first example, a barrier film 205 suppresses diffusion of Cu is formed on the surface of the wafer W including the trench 203 and the via hole 204 (step 13, FIG. 13C).

Next, a liner film 214 as a layer to be wetted is formed on the barrier film 205 in order to ensure a wettability to a Cu alloy or Cu filled in the trench 203 and the via hole 204 (step 14, FIG. 13D). As the liner film 214, it is preferable to use a Ru film or a Co film having an excellent wettability to Cu or a Cu alloy. The liner film 214 is preferably formed with a small thickness of, e.g., 1 nm to 5 nm, in order to obtain a low resistance of a wiring by increasing a volume of Cu to be filled. Due to the liner film 214, when Cu or a Cu alloy is filled by the following PVD, the mobility thereof can be improved and the generation of overhang that blocks the opening of the trench or the via hole can be prevented. Therefore, Cu can be reliably filled by the PVD without generating a void in the fine trench or the fine via hole.

The liner film 214 is preferably formed by CVD. Accordingly, a thinner liner film 214 can be formed while ensuring a good step coverage. In the case of using a Ru film as the liner film 214, it is preferable to form a film by thermal CVD while using ruthenium carbonyl (Ru₃(CO)₁₂) as a film forming material. Another film forming material other than Ru₃(CO)₁₂ may be a pentadienyl compound of ruthenium, e.g., (cyclopentadienyl) (2,4-dimethylpentadienyl) ruthenium, bis(cyclopentadienyl) (2,4-methylpentadienyl)ruthenium, (2,4-dimethylpentadienyl) (ethylcyclopentadienyl) ruthenium, bis(2, 4-methylpentadienyl) (ethylcyclopentadienyl)ruthenium. Instead of the CVD, ALD or PVD may also be used for film formation. In the case of using a Co film, the film formation may be carried out by CVD, ALD, or PVD.

Next, a Cu-based film 215 made of Cu or a Cu alloy is formed on the surface of the liner film 214 by PVD under the condition that the mobility of Cu or a Cu alloy on the liner film 214 can be ensured, and the Cu-based film 215 is filled in the trench 203 and the via hole 204 (step 15, FIG. 13E). The film formation at this time is preferably performed by iPVD in which ions are attracted to the wafer where the mobility of Cu or Cu alloy on the liner film 214 can be relatively easily ensured.

In the conventional film formation using the PVD, the overhang that blocks the opening of the trench or the hole is easily formed due to agglomeration of Cu. However, when the iPVD is applied, the film forming action of Cu ions and the etching action of ions (Ar ions) of the plasma generation gas are controlled by adjusting the bias power applied to the wafer so that Cu or Cu alloy can be moved on the liner film 214 having a high wettability to Cu or Cu alloy without agglomeration to thereby suppress the formation of the overhang. As a consequence, good fillability can be obtained without generating a void even in a narrow trench or a narrow hole. At this time, in order to ensure mobility of Cu and obtain good fillability, it is preferable to perform a high-temperature process (in a temperature ranging from 65° C. to 400° C. and more preferably ranging from 230° C. to 350° C.) in which Cu is migrated. By performing the film formation using the PVD at such a high temperature, Cu crystal grains can grow, thereby reducing the resistance of the Cu wiring.

When a Cu alloy is used as the Cu-based film 215, Cu—Al and Cu—Mn may be used. As another Cu alloy, it is also possible to use Cu—Mg, Cu—Ag, Cu—Sn, Cu—Pb, Cu—Zn, Cu—Pt, Cu—Au, Cu—Ni, Cu—Co, Cu—Ti or the like.

Next, if necessary, a deposit layer 216 is formed on the Cu-based film 215 by performing Cu plating on the surface of the wafer W in order to prepare a planarization process to be performed later (step 16, FIG. 13F). Then, annealing is performed (step 17, FIG. 13G)). The deposit layer 216 may be formed by PVD.

Thereafter, as in the step 7 of the first example, the planarization process is performed by CMP to remove the deposit layer 216, the Cu-based film 215, the liner film 214, and the barrier film 205 which are laminated on the surface of the wafer W (step 18, FIG. 13H). Accordingly, the Cu wiring 210 connected to the underlying Cu wiring 211 is formed.

<Film Forming System>

Hereinafter, a film forming system used for performing the semiconductor device manufacturing method will be described.

(Film Forming System Used for First Example)

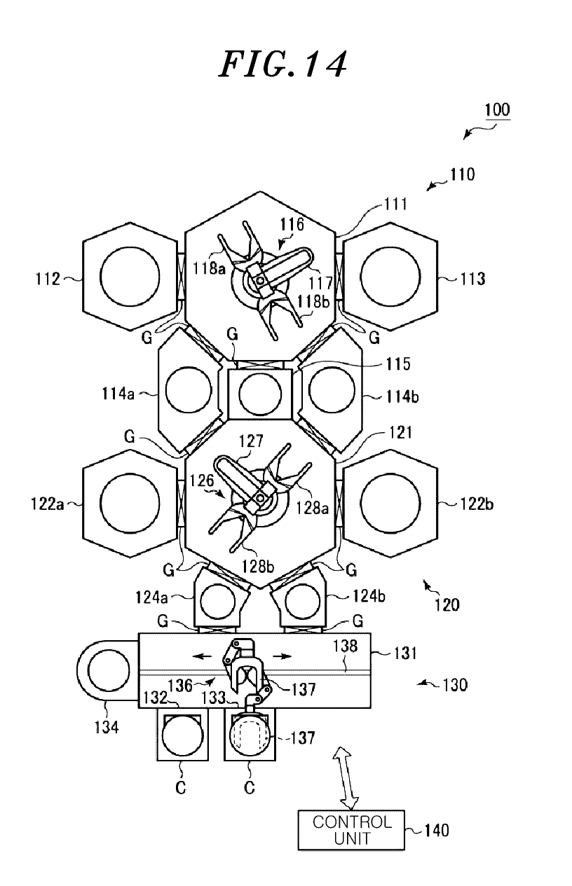

FIG. 14 schematically shows a film forming system used in the first example of the semiconductor device manufacturing method.

The film forming system 100 includes a first processing unit 110 for forming a barrier film and a Cu-based seed film, a second processing unit 120 for supplying a Mn-containing material that is reducing species to a via hole bottom, a loading/unloading unit 130, and a control unit 140. The film forming system 100 performs processes from a degas process up to formation of a Cu-based seed film on the wafer W having a trench and a via hole formed in a predetermined pattern.

The first processing unit 110 includes a first vacuum chamber 111, a barrier film forming apparatus 112 and a Cu-based seed film forming apparatus 113 which are connected to walls of the first vacuum chamber 111. The barrier film forming apparatus 112 and the Cu-based seed film forming apparatus 113 are disposed at opposite positions. The barrier film forming apparatus 112 forms the above-described barrier film 205. The Cu-based seed film forming apparatus 113 forms the above-described Cu-based seed film 206. The barrier film forming apparatus 112 and the Cu-based seed film forming apparatus 113 are configured as a PVD apparatus. As the PVD apparatus, an iPVD apparatus is preferably used. The plasma sputtering apparatus shown in FIG. 3 may be preferably used.

Degas chambers 114a and 114b each for performing a degas process on the wafer W are connected to walls of the first vacuum transfer chamber 111 which face the second processing unit 120. Further, a delivery chamber 115 through which the wafer W is transferred between the first vacuum transfer chamber 111 and a second vacuum transfer chamber 121 to be described later is connected to a wall of the first vacuum transfer chamber 111 which is disposed between the degas chambers 114a and 114b.

The barrier film forming apparatus 112, the Cu-based seed film forming apparatus 113, the degas chambers 114a and 114b, and the delivery chamber 115 are connected to the respective sides of the first vacuum transfer chamber 111 through gate valves G. They communicate with the first vacuum transfer chamber 111 by opening the corresponding gate valves G and are isolated from the first vacuum transfer chamber 111 by closing the corresponding gate valves G.

The inside of the first vacuum transfer chamber 111 is maintained at a predetermined vacuum atmosphere. Provided in the first vacuum transfer chamber 111 is a first transfer mechanism 116 for loading and unloading the wafer W. The first transfer mechanism 116 is disposed substantially at the center of the first vacuum transfer chamber 111 and has a rotatable and extensible/contractible portion 117. The rotatable and extensible/contractible portion 117 has, at its leading end, two holding arms 118a and 118b for holding the wafer W. The first transfer mechanism 116 loads and unloads the wafer W into and from the barrier film forming apparatus 112, the Cu-based seed film forming apparatus 113, the degas chambers 114a and 114b, and the delivery chamber 115.

The second processing apparatus 120 includes: a second vacuum transfer chamber 121 and two Mn film forming apparatuses 122a and 122b respectively connected to opposite walls of the second vacuum transfer chamber 121. The Mn film forming apparatuses 122a and 122b may be used to supply a Mn-containing material as the reducing species to the via hole bottom. As the Mn film forming apparatuses 122a and 122b, the CVD apparatus shown in FIG. 5 or the plasma sputtering apparatus shown in FIG. 3 may be used. The Mn film forming apparatuses 122a and 122b are disposed at opposite positions.

The degas chambers 114a and 114b are connected to walls of the second vacuum transfer chamber 121 which face the first processing unit 110, and the delivery chamber 115 is connected to a wall of the second vacuum transfer chamber 121 between the degas chambers 114a and 114b. In other words, the delivery chamber 115 and the degas chambers 114a and 114b are provided between the first vacuum transfer chamber 111 and the second vacuum transfer chamber 121, and the degas chambers 114a and 114b are disposed at both sides of the delivery chamber 115. Moreover, load-lock chambers 124a and 124b capable of atmospheric transfer and vacuum transfer are respectively connected to walls of the second vacuum transfer chamber 121 which face the loading/unloading unit 130.

The Mn film forming apparatuses 122a and 122b, the degas chambers 114a and 114b, and the load-lock chambers 124a and 124b are connected to the respective sides of the second vacuum transfer chamber 121 through gate valves G. They communicate with the second vacuum transfer chamber 121 by opening the corresponding valves G and are isolated from the second vacuum transfer chamber 121 by closing the corresponding gate valves G. The delivery chamber 115 is connected to the second transfer chamber 121 without providing a gate valve therebetween.

The inside of the second vacuum transfer chamber 121 is maintained at a predetermined vacuum atmosphere. Provided in the second vacuum transfer chamber 121 is a second transfer mechanism 126 for loading and unloading the wafer W into and from the Mn film forming apparatuses 122a and 122b, the degas chambers 114a and 114b, the load-lock chambers 124a and 124b and the delivery chamber 115. The second transfer mechanism 126 is disposed substantially at the center of the second vacuum transfer chamber 121 and has a rotatable and extensible/contractible portion 127. The rotatable and extensible/contractible portion 127 has, at its leading end, two holding arms 128a and 128b for holding the wafer W. The two holding arms 128a and 128b are attached to the rotatable and extensible/contractible portion 127 to face opposite directions.

The loading/unloading unit 130 is provided opposite to the second processing unit 120 with the load-lock chambers 124a and 124b interposed therebetween. The loading/unloading unit 130 has an atmospheric transfer chamber 131 connected to the load-lock chambers 124a and 124b. A filter (not shown) for forming a downflow of clean air is provided at an upper portion of the atmospheric transfer chamber 131. Gate valves G are provided between the load-lock chambers 124a and 124b and a wall of the atmospheric transfer chamber 131. Provided at a wall of the atmospheric transfer chamber 131 opposite to the wall connected to the load-lock chambers 124a and 124b through the Gate valves G are two connection ports 132 and 133 each for connecting carriers C accommodating therein wafers W as substrates to be processed. Further, an alignment chamber 134 is provided at a side of the atmospheric transfer chamber 131, and alignment of the wafer W is executed therein. Provided in the atmospheric transfer chamber 131 is an atmospheric transfer mechanism 136 for loading and unloading the wafer W into and from the carrier C and the load-lock chambers 124a and 124b. The atmospheric transfer mechanism 136 has two multi-joint arms and can move on a rail 138 along the arrangement direction of the carriers C. The atmospheric transfer mechanism 136 transfers wafers W while mounting the wafer W on each of hands 137 provided at leading ends of the respective arms.

The controller 140 is configured to control the respective components of the film forming system 100. The controller 140 includes a process controller having a microprocessor (computer) for controlling the respective components, a user interface and a storage unit. The user interface includes a keyboard through which an operator inputs a command to manage the film forming system 100, a display for visually displaying the operational states of the film forming system 100 and the like. The storage unit stores therein control programs to be used in realizing various processes performed in the film forming system 100 under the control of the process controller, and programs, i.e., processing recipes, to be used in controlling the respective components of the processing apparatuses to carry out processes under processing conditions and various data. The processing recipes are stored in a storage medium. The storage medium may be a hard disk, a portable medium such as a CD-ROM and a DVD, a semiconductor memory such as a flash memory or the like. A specific recipe is read out from the storage unit under an instruction from the user interface and is executed by the process controller. Accordingly, a desired process is performed in the film forming system 100 under the control of the process controller.

In the film forming system 100, the wafer W having the trench and the via hole formed in a predetermined pattern is unloaded from the carrier C and is loaded into the load-lock chamber 124a or 124b by the atmospheric transfer mechanism 136. After the pressure in the load-lock chamber 124a or 124b is decreased to a vacuum level substantially equivalent to that in the second vacuum transfer chamber 121, the wafer W is unloaded from the load-lock chamber 124a or 124b to be loaded into the degas chamber 114a or 114b through the second vacuum transfer chamber 121 by the second transfer mechanism 126. Thus, the wafer W is subjected to the degas process. Thereafter, the wafer W is unloaded from the degas chamber 114a or 114b and is loaded into the Mn film forming apparatus 122a or 122b by the second transfer mechanism 126. Thus, the via hole bottom cleaning process is performed by supplying a Mn-containing material to the wafer W, thereby reducing and removing copper oxide of the underlying Cu wiring. Then, the wafer W is unloaded from the Mn film forming apparatus 122a or 122b to be loaded into the delivery chamber 115 by the second transfer mechanism 126. Next, the wafer W is unloaded from the delivery chamber 115 and loaded into the barrier film forming apparatus 112 through the first vacuum transfer chamber 111 by the first transfer mechanism 116. Thus, the barrier film is formed as described above. After the barrier film is formed, the wafer W is unloaded from the barrier film forming apparatus 112 by the first transfer mechanism 116 and loaded into the Cu-based seed film forming apparatus 113. Thus, a Cu-based seed film made of Cu or Cu alloy is formed. Next, the wafer W is unloaded by the first transfer mechanism 116 and transferred to the delivery chamber 115. Then, the wafer W is unloaded from the delivery chamber 115 and transferred to the load-lock chamber 124a or 124b by the second transfer mechanism 126. After the pressure in the load-lock chamber is returned to the atmospheric pressure, the wafer W having the Cu-based seed film is unloaded and is returned to the carrier C by the atmospheric transfer mechanism 136. Such processes are repeated for all of wafers W in the carrier C.

In accordance with the film forming system 100, via hole bottom cleaning, forming the barrier film, and forming the Cu-based seed film can be performed in the vacuum atmosphere without being exposed to the atmosphere. Accordingly, oxidation between layers can be prevented and a high-performance semiconductor device can be obtained.

The wafer W unloaded from the film forming system 100 is transferred to the Cu plating device and subjected to Cu plating, and then the wafer W is transferred to the CMP device and subjected to CMP processing.

(Film Forming System Used for Second Example)

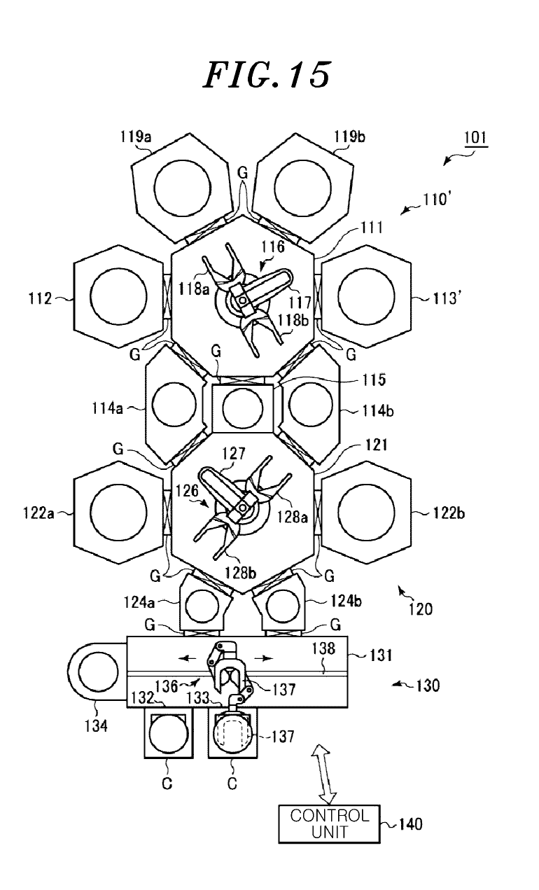

FIG. 15 schematically shows a film forming system used in the second example of the semiconductor device manufacturing method.

A film forming system 101 includes a first processing unit 110′ for barrier film formation, liner film formation and Cu-based film formation, the second processing unit 120 for supplying an Mn-containing material as reducing species to a via hole bottom, the loading/unloading unit 130 and the control unit 140. The film forming apparatus 122a or 122b performs on the wafer W processes from a degas process up to forming the Cu-based film by filling the trench and the via hole with Cu or Cu alloy.

As in the case of the first processing unit 110 of the film forming system 100 shown in FIG. 14, the first processing unit 110′ includes a first vacuum transfer chamber 111, a barrier film forming apparatus 112, degas chambers 114a and 114b, a delivery chamber 115, and a first transfer mechanism 116. In this example, an embedded Cu-based film forming apparatus 113′ is provided instead of the Cu-based seed film forming apparatus 113 of the first processing unit 110. Further, two liner film forming apparatuses 119a and 119b are connected to other walls of the first vacuum transfer chamber 111. The Cu-based film forming apparatus 113′ fills Cu or Cu alloy in the trench and the via hole by forming the Cu-based film 215 as described above. The Cu-based film forming apparatus 113′ is configured as an iPVD apparatus. The plasma sputtering apparatus shown in FIG. 3 may be preferably used as the Cu-based film forming apparatus 113′. The liner film forming apparatuses 119a and 119b form a liner film 214 as a layer to be wetted. The CVD apparatus shown in FIG. 5 may be preferably used as the liner film forming apparatuses 119a and 119b.

The second processing unit 120, the loading/unloading unit 130 and the control unit 140 have the same configurations as those of the film forming system 100.

In this film forming system 101, the wafer W having the trench and the via hole formed in a predetermined pattern is unloaded from the carrier C and is loaded into the load-lock chamber 124a or 124b by the atmospheric transfer mechanism 136. After the pressure in the load-lock chamber 124a or 124b is decreased to a vacuum level substantially equivalent to that in the second vacuum transfer chamber 121, the wafer W is unloaded from the load-lock chamber 124a or 124b to be loaded into the degas chamber 114a or 114b through the second vacuum transfer chamber 121 by the second transfer mechanism 126. Thus, the wafer W is subjected to the degas process. Thereafter, the wafer W is unloaded from the degas chamber 114a or 114b and is loaded into the Mn film forming apparatus 122a or 122b by the second transfer mechanism 126. The via hole bottom cleaning is performed by supplying a Mn-containing material to the wafer W. Thus, copper oxide of the underlying Cu wiring is reduced and removed. Then, the wafer W is unloaded from the Mn film forming apparatus 122a or 122b to be loaded into the delivery chamber 115 by the second transfer mechanism 126. Next, the wafer W is unloaded from the delivery chamber 115 and loaded into the barrier film forming apparatus 112 through the first vacuum transfer chamber 111 by the first transfer mechanism 116. Thus, the barrier film as described above is formed. After the barrier film is formed, the wafer W is unloaded from the barrier film forming apparatus 112 and loaded into the liner film forming apparatus 119a or 119b by the first transfer mechanism 116. Thus, the liner film, e.g., a Ru film, is formed. After the liner film is formed, the wafer W is unloaded from the liner film forming apparatus 119a or 119b and loaded into the Cu-based film forming apparatus 113′ by the first transfer mechanism 116. Thus, the Cu-based film made of Cu or Cu alloy is formed to fill the trench and the via. Next, the wafer W is unloaded from the Cu-based film forming apparatus 113′ and transferred to the delivery chamber 115 by the first transfer mechanism 116. Then, the wafer W is unloaded from the delivery chamber 115 and transferred to the load-lock chamber 124a or 124b by the second transfer mechanism 126. After the pressure in the load-lock chamber is returned to the atmospheric pressure, the wafer W in which the trench and the via hole are filled by the formation of the Cu-based film is unloaded and is returned to the carrier C by the atmospheric transfer mechanism 136. Such processes are repeated for all of wafers W in the carrier C.

In accordance with the film forming system 101, the via hole bottom cleaning, forming the barrier film, forming the liner film, and forming the Cu-based film can be performed in the vacuum atmosphere without being exposed to the atmosphere. Accordingly, oxidation between layers can be prevented and a high-performance semiconductor device can be obtained.

The wafer W unloaded from the film forming system 101 is transferred to the Cu plating device, if necessary. Thus, an additional layer is formed by Cu plating. Then, the wafer W is transferred to the CMP device and subjected to CMP processing. The additional layer may be formed by the Cu-based film forming apparatus 113′ of the film forming system 101.

<Other Application>

While the embodiments have been described, the present disclosure may be variously modified without being limited to the above-described embodiments. For example, in the above-described embodiments, a technique for supplying the reducing species to the via hole bottom by PVD or CVD has been applied. However, the technique is not limited thereto as long as an appropriate amount of the reducing species can be supplied to the via hole bottom.

For example, in the above-described embodiments, the semiconductor wafer has been described as an example of the substrate to be processed. However, the semiconductor wafer includes a compound semiconductor such as GaAs, SiC, GaN or the like as well as a typical silicon wafer. The substrate is not limited to the semiconductor wafer, and the present disclosure may also be applied to a glass substrate used for a FPD (flat panel display) such as a liquid crystal display or the like, a ceramic substrate, or the like.

The film forming system is not limited to a system divided into the first processing unit and the second processing unit shown in FIGS. 14 and 15, and may also be a system having another configuration in which the first processing unit and the second processing unit are formed as one unit.

While the disclosure has been shown and described with respect to the embodiments, it will be understood by those skilled in the art that various changes and modifications may be made without departing from the scope of the disclosure as defined in the following claims.

What is claimed is:

1. A method of cleaning a bottom of a via hole, by removing a copper oxide on a surface of an underlying Cu wiring exposed at the bottom of the via hole before forming a Cu wiring in a trench and the via hole extended between the trench and the underlying Cu wiring, the trench and the via hole being formed in a predetermined pattern in an interlayer insulating film of a substrate, the method comprising:
supplying to the bottom of the via hole reducing species containing a metal, the metal which has a higher oxidation tendency than Cu and whose oxide has a lower electrical resistance than the copper oxide, in a state capable of reducing the copper oxide; and
removing the copper oxide by reducing the copper oxide and generating the oxide of the metal through a reaction between the metal contained in the reducing species and the copper oxide on the surface of the underlying Cu wiring.

2. The method of claim 1, wherein the metal is Mn, Zn, Sn or In.

3. The method of claim 1, wherein the metal is deposited as the reducing species by PVD on a surface of the substrate which includes the bottom of the via hole, and the deposited metal and the copper oxide on the surface of the underlying Cu wiring react with each other by heating.

4. The method of claim 1, wherein a film containing the metal is formed by CVD on a surface of the substrate which includes the bottom of the via hole by using a compound gas containing the metal as the reducing species, and the metal contained in the film and the copper oxide on the surface of the underlying Cu wiring react with each other.

5. A method of cleaning a bottom of a via hole by removing a copper oxide on a surface of an underlying Cu wiring exposed at the bottom of the via hole before forming a Cu wiring in a trench and the via hole extended between the trench and the underlying Cu wiring, the trench and the via hole being formed in a predetermined pattern in an interlayer insulating film of a substrate, the method comprising:
supplying a Mn-containing material which contains Mn in a state capable of reducing the copper oxide to the bottom of the via hole as reducing species; and
removing the copper oxide by reducing the copper oxide and generating a manganese oxide through a reaction between the Mn-containing material and the copper oxide on the surface of the underlying Cu wiring.

6. The method of claim 5, wherein Mn is deposited as the Mn-containing material by PVD on a surface of the substrate which includes the bottom of the via hole, and the deposited Mn and the copper oxide on the surface of the underlying Cu wiring react with each other by heating.

7. The method of claim 5, wherein a manganese film is formed by CVD on a surface of the substrate which includes the bottom of the via hole by using an organic Mn compound gas as the Mn-containing material, and the manganese film and the copper oxide on the surface of the underlying Cu wiring react with each other.

8. The method of claim 1, wherein, before the cleaning of the bottom of the via hole, moisture is removed by performing a degas process on the substrate.

9. A method of manufacturing a semiconductor device, which forms a Cu wiring connected to an underlying Cu wiring by filling a Cu-based film in a trench and the via hole extended between the trench and the underlying Cu wiring, the trench and the via hole being formed in a predetermined pattern in an interlayer insulating film of a substrate, the method comprising:
cleaning a bottom of the via hole by supplying reducing species containing a metal which has a higher oxidation tendency than Cu and whose oxide has a lower electrical resistance than a copper oxide formed on the surface of the underlying Cu wiring, in a state capable of reducing the copper oxide, and removing the copper oxide by reducing the copper oxide and generating the oxide of the metal through a reaction between the metal contained in the reducing species and the copper oxide;
forming a barrier film on a surface of the interlayer insulating film;
filling a Cu-based film in the trench and the via hole; and
forming a Cu wiring by polishing a surface of the substrate including the Cu-based film.

10. The method of claim 9, wherein in the cleaning the bottom of the via hole, the metal is Mn, Zn, Sn, or In.

11. The method of claim 9, wherein in the cleaning the bottom of the via hole, the metal is deposited as the reducing species by PVD on a surface of the substrate which includes the bottom of the via hole, and the deposited metal and the copper oxide on the surface of the underlying Cu wiring react with each other by heating.

12. The method of claim 9, wherein in the cleaning the bottom of the via hole, a film containing the metal is formed by CVD on a surface of the substrate which includes the bottom of the via hole by using a compound gas containing the metal as the reducing species, and the metal contained in the film and the copper oxide on the surface of the underlying Cu wiring react with each other.

13. A method of manufacturing a semiconductor device, which forms a Cu wiring connected to an underlying Cu wiring by filling a Cu-based film in a trench and a via hole extended between the trench and the underlying Cu wiring, the trench and the via hole being formed in a predetermined pattern in an interlayer insulating film of a substrate, the method comprising:
cleaning the bottom of the via hole by supplying to the bottom of the via hole a Mn-containing material which contains Mn in a state capable of reducing a copper oxide formed on the surface of the underlying Cu wiring as reducing species, and removing the copper oxide by reducing the copper oxide and generating a manganese oxide through a reaction between the Mn-containing material and the copper oxide;
forming a barrier film on the surface of the interlayer insulating film;
filling the Cu-based film in the trench and the via hole; and
forming a Cu wiring by polishing a surface of the substrate including the Cu-based film.

14. The method of manufacturing semiconductor device of claim 13, wherein in the cleaning the bottom of a via hole, a metal Mn as the Mn-containing material is deposited by PVD on the surface of the substrate which includes the bottom of a via hole, and the deposited Mn and the copper oxide on the surface of the underlying Cu wiring react with each other by heating.

15. The method of claim 13, wherein in the cleaning the bottom of the via hole, a manganese film is formed by CVD on the surface of the substrate which includes the bottom of the via hole by using an organic Mn compound gas as the Mn-containing material, and the manganese film and the copper oxide on the surface of the underlying Cu wiring react with each other.

16. The method of claim 9, wherein, before the cleaning of the bottom of the via hole, moisture is removed by performing a degas process on the substrate.

17. The method of claim 9, wherein the filling the Cu-based film in the trench and the via hole is performed by Cu plating.

18. The method of claim 9, wherein the forming the Cu-based film in the trench and the via hole is performed by PVD.

19. The method of claim 18, further comprising, before the filling the Cu-based film in the trench and the via hole, forming a layer to be wetted that is made of a metal, which is wetted by cu or cu alloy, on the surface of the barrier film,
wherein the filling the Cu-based film in the trench and the via hole is performed by PVD under a condition in which the Cu-based film is movable on the layer to be wetted.

20. The method of claim 19, wherein the layer to be wetted is made of Ru or Co.

21. The method of claim 19, wherein the layer to be wetted is formed by CVD.
